(19) United States
(12) Patent Application Publication
(10) Pub. No.: US 2021/0305023 A1
(43) Pub. Date: Sep. 30, 2021

(54) EDGE RING AND PLASMA PROCESSING APPARATUS

(71) Applicant: Tokyo Electron Limited, Tokyo (JP)

(72) Inventors: Masahiro OGASAWARA, Miyagi (JP); Hidetoshi HANAOKA, Miyagi (JP); Masashi IKEGAMI, Miyagi (JP); Naoyuki SATOH, Miyagi (JP); Toshiya TSUKAHARA, Miyagi (JP)

(21) Appl. No.: 17/195,787

(22) Filed: Mar. 9, 2021

(30) Foreign Application Priority Data
Mar. 30, 2020 (JP) 2020-060485

(51) Int. Cl. H01J 37/32; H01L 21/687; H01L 21/311

(52) U.S. Cl. CPC H01J 37/32642; H01J 37/32715; H01J 2237/334; H01L 21/31116; H01L 21/68757

(57) ABSTRACT

An edge ring formed of a material including boron carbide and silicon carbide is provided. The content by percentage of the boron carbide contained in the material is in a range between 30% and 50%.

### CROSS-REFERENCE TO RELATED APPLICATIONS

This patent application is based upon and claims priority to Japanese Patent Application No. 2020-060485 filed on Mar. 30, 2020, the entire contents of which are incorporated herein by reference.

### TECHNICAL FIELD

The present disclosure relates to an edge ring and a plasma processing apparatus.

### BACKGROUND

In the plasma processing apparatus, an edge ring is placed to surround the periphery of the substrate to be mounted on the mounting platform. The edge ring is used to increase uniformity of a plasma by extending the region of distribution of the plasma above the wafer to the outside of the wafer.

In recent years, in order to extend the life of an edge ring, it has been proposed to use silicon carbide (SiC), which is more rigid than silicon (Si), as a material for the edge ring (see Patent Document 1, for example).

### RELATED ART DOCUMENT

### Patent Document

[Patent Document 1] Japanese Laid-open Patent Application Publication No. 2018-107433

### SUMMARY

The present disclosure provides an edge ring and a plasma processing apparatus capable of improving plasma resistance.

According to one aspect of the present disclosure, an edge ring formed of a material including boron carbide and silicon carbide is provided. The content by percentage of the boron carbide contained in the material is in a range between 30% and 50%.

### BRIEF DESCRIPTION OF THE DRAWINGS

FIG. 1 is a cross-sectional view illustrating an example of a plasma processing apparatus according to an embodiment;

FIG. 2 illustrates an example of the film structure formed on a substrate according to the embodiment;

FIGS. 3A and 3B are diagrams illustrating an experiment regarding abrasion of an edge ring according to the embodiment;

FIG. 4 illustrates an example of results of the experiment regarding abrasion of the edge ring according to the embodiment;

FIG. 5 is a diagram illustrating an example of experimental results regarding abrasion of a test piece of the edge ring according to the embodiment; and

FIGS. 6A to 6C are diagrams illustrating examples of results of experiments of etching processing of a substrate performed in the plasma processing apparatus in which the edge ring according to the embodiment is placed.

### DETAILED DESCRIPTION OF EMBODIMENTS

Hereinafter, embodiments for carrying out the present disclosure will be described with reference to the drawings. In each drawing, the same components are indicated by the same reference numerals, and redundant descriptions may be omitted.

### Plasma Processing Apparatus

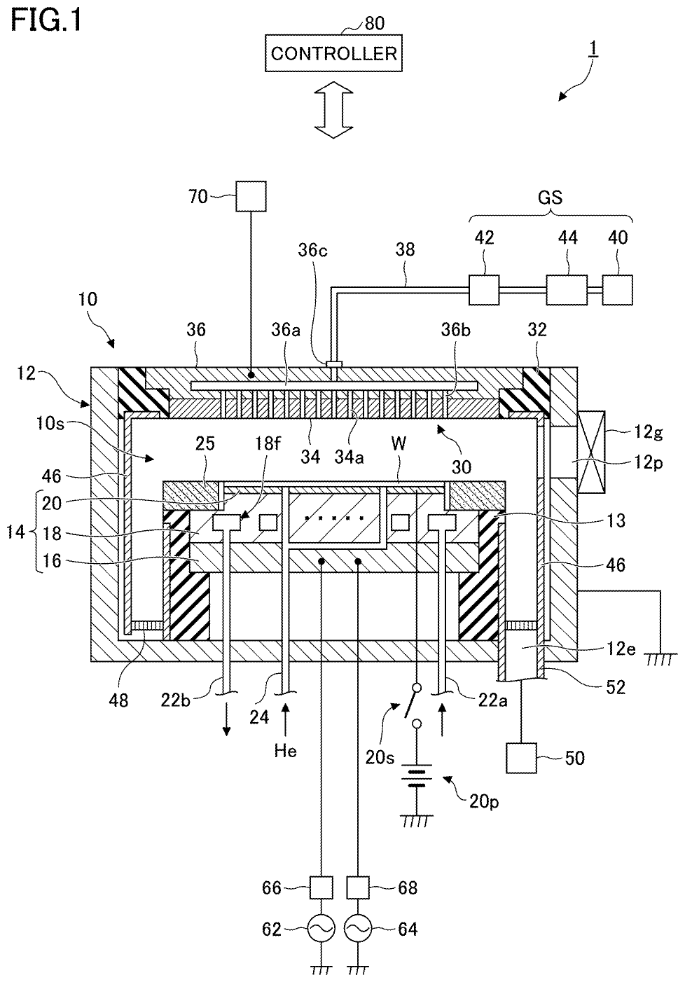

A plasma processing apparatus 1 according to an embodiment will be described with reference to FIG. 1. FIG. 1 is a cross-sectional diagram illustrating an example of a plasma processing apparatus 1 according to an embodiment. The plasma processing apparatus 1 includes a chamber 10. The chamber 10 provides an interior space 10s therein. The chamber 10 includes a chamber body 12. The chamber body 12 has a generally cylindrical shape. The interior space 10s is provided inside the chamber body 12. The chamber body 12 is formed, for example, of aluminum. A corrosion resistant film is provided on the inner wall surface of the chamber body 12. The corrosion resistant film can be an anodized oxide formed from a ceramic such as alumina (aluminum oxide) or yttrium oxide.

A passage 12p is formed in the side wall of the chamber body 12. A substrate W passes through the passage 12p when the substrate W is transferred between the interior space 10s and the exterior of the chamber 10. The passage 12p can be opened and closed by a gate valve 12g. The gate valve 12g is provided along the side wall of the chamber body 12.

A support 13 is provided on the bottom of the chamber body 12. The support 13 is formed of an insulating material. The support 13 has a generally cylindrical shape. The support 13 extends upward from the bottom of the chamber body 12 in the interior space 10s. On the support 13, an edge ring (also referred to as a focus ring) is provided, which surrounds the substrate W. The edge ring 25 has a generally annular shape, and is formed of a material including boron carbide (B₄C) and silicon carbide (SiC).

The plasma processing apparatus 1 further includes a stage 14. The stage 14 is supported by the support 13. The stage 14 is provided in the interior space 10s. The stage 14 is configured to support the substrate W in the chamber 10, i.e., the interior space 10s.

The stage 14 includes a lower electrode 18 and an electrostatic chuck 20 according to one exemplary embodiment. The stage 14 may further include an electrode plate 16. The electrode plate 16 is formed from a conductor, such as aluminum, and has a general disk shape. The lower electrode 18 is provided on the electrode plate 16. The lower electrode 18 is formed of a conductor, such as aluminum, and has a general disk shape. The lower electrode 18 is electrically connected to the electrode plate 16. The outer periphery of the lower electrode 18 and the outer periphery of the electrode plate 16 are surrounded by the support 13.

The electrostatic chuck 20 is provided on the lower electrode 18. The electrode of the electrostatic chuck 20 is connected to a direct-current (DC) power supply 20p via a switch 20s. When voltage is applied from the DC power supply 20p to the electrode of the electrostatic chuck 20, the substrate W is attracted to the electrostatic chuck 20 by electrostatic attracting force. The electrostatic chuck 20 supports the substrate W and the edge ring 25.

A flow passage 18f is provided within the lower electrode 18. A heat exchange medium (e.g., refrigerant) is supplied to the flow passage 18f from a chiller unit provided outside the chamber 10 via a pipe 22a. The heat exchange medium supplied to the flow passage 18f is returned to the chiller unit via a pipe 22b. in the plasma processing apparatus 1, the temperature of the substrate W placed on the electrostatic chuck 20 is regulated by heat exchange between the heat exchange medium and the lower electrode 18.

The plasma processing apparatus 1 is provided with a gas supply line 24. The gas supply line 24 supplies a heat transfer gas (e.g., He gas) from the heat transfer gas supply mechanism to a gap between the upper surface of the electrostatic chuck 20 and the lower surface of the substrate W.

The plasma processing apparatus 1 further includes an upper electrode 30. The upper electrode 30 is located above the stage 14. The upper electrode 30 is supported at the top of the chamber body 12 via a member 32. The member 32 is formed of an insulating material. The upper electrode 30 and the member 32 occlude the opening of the chamber body 12 formed at the top of the chamber body 12.

The upper electrode 30 may include a top plate 34 and a support 36. The lower surface of the top plate 34 defines the interior space 10s. The top plate 34 may be formed of a low resistance conductor or semiconductor with low Joule heat. Multiple gas discharge holes 34a are formed in the top plate 34. The multiple gas discharge holes 34a penetrate the top plate 34 in its thickness direction.

The support 36 removably supports the top plate 34. The support 36 is formed of an electrically conductive material such as aluminum. Inside the support 36, a gas diffusion chamber 36a is provided. Multiple gas holes 36b are formed in the support 36, and the multiple gas holes 36b extend downward from the gas diffusion chamber 36a. The multiple gas holes 36b communicate with the multiple gas discharge holes 34a, respectively. A gas inlet 36c is formed in the support 36, and the gas inlet 36c is connected to the gas diffusion chamber 36a. A gas supply line 38 is connected to the gas inlet 36c.

A gas supply section GS, which includes gas sources 40, flow controllers 44, and valves 42, is connected to the gas supply line 38. The gas sources 40 are connected to the gas supply line 38 via the flow controllers 44 and the valves 42. The valves 42 include multiple open and close valves. Each of the flow controllers 44 is a mass flow controller or a pressure controlled flow controller. Each of the gas sources 40 is connected to the gas supply line 38 via a corresponding flow controller of the flow controllers 44 and a corresponding open/close valve of the valves 42. A power supply 70 is connected to the upper electrode 30. The power supply 70 applies voltage to the upper electrode 30 to draw positive ions present in the interior space 10s into the top plate 34.

In the plasma processing apparatus 1, a shield 46 is removably provided along the inner wall surface of the chamber body 12. A shield 46 is also provided around the outer periphery of the support 13. The shield 46 prevents reaction products, such as etching byproducts, from adhering to the chamber body 12. The shield 46 is made by, for example, forming a corrosion resistant film on the surface of a member formed of aluminum. The corrosion resistant film may be formed of oxides such as alumina or yttrium oxide.

A baffle plate 48 is provided between the side wall of the support 13 and the inner side wall of the chamber body 12. The baffle plate 48 is made by, for example, forming a corrosion resistant film on the surface of a member formed of aluminum. The corrosion resistant film may be formed of oxides such as alumina or yttrium oxide. Multiple through-holes are formed in the baffle plate 48. Below the baffle plate 48, an exhaust port 12e is provided at the bottom of the chamber body 12. An exhaust device 50 is connected to the exhaust port 12e via an exhaust pipe 52. The exhaust device 50 includes a vacuum pump such as a pressure regulating valve or a turbomolecular pump.

The plasma processing apparatus 1 includes a first radio frequency power supply 62 that applies radio frequency power for plasma generation. The first radio frequency power supply 62 supplies power at a first radio frequency to generate a plasma from the process gas within the chamber 10. The first radio frequency is, for example, in the range of 27 MHz to 100 MHz.

The first radio frequency power supply 62 is electrically connected to the electrode plate 16 via a matcher 66. The matcher 66 includes matching circuitry. The matching circuitry of the matcher 66 is configured to cause impedance of the load seen from the first radio frequency power supply 62 to match the output impedance of the first radio frequency power supply 62. In another embodiment, the first radio frequency power supply 62 may be electrically connected to the upper electrode 30 via the matcher 66.

The plasma processing apparatus 1 may further include a second radio frequency power supply 64 that applies radio frequency power for drawing ions. The second radio frequency power supply 64 provides power at a second radio frequency lower than the first radio frequency. The second radio frequency should be a frequency primarily suitable for drawing ions to the substrate W. For example, the second radio frequency is in the range of 400 kHz to 13.56 MHz. In another embodiment, the second radio frequency power supply 64 may supply a pulsed voltage having a rectangular waveform.

The second radio frequency power supply 64 is electrically connected to the electrode plate 16 via a matcher 68. The matcher 68 includes matching circuitry. The matching circuitry of the matcher 68 is configured to cause impedance of the load seen from the second radio frequency power supply 64 to match the output impedance of the second radio frequency power supply 64.

The plasma processing apparatus 1 may further include a controller 80. The controller 80 may be a computer including a processor, a storage device such as a memory, an input device, a display device, an input/output interface of a signal, or the like. The controller 80 controls each part of the plasma processing apparatus 1. In the controller 80, an operator can perform input operations of commands to manage the plasma processing apparatus 1, by using the input device. The controller 80 can also display an operation status of the plasma processing apparatus 1 on the display device. The storage device of the controller 80 stores a control program and recipe data. The control program is executed by the processor of the controller 80 to cause the plasma processing apparatus 1 to perform various processes. As the processor of the controller 80 executing the control program controls each portion of the plasma processing apparatus 1 in accordance with the recipe data, various processes, such as plasma processing, are performed in the plasma processing apparatus 1.

### Edge Ring

The edge ring 25 is disposed to surround the periphery of the substrate W placed on the stage 14, and is exposed to a plasma during processing of the substrate W. In a case in which silicon (Si) is used as the material of the edge ring 25, the edge ring 25 is gradually abraded by processing the substrate W with a plasma. Abrasion of the edge ring 25 affects etching characteristics of the substrate W, such as occurrence of tilting of the incident angle of ions incident on the edge region of the substrate W. For this reason, an edge ring that has been worn to a certain extent is replaced with a new edge ring.

In recent years, employing silicon carbide, which is a more rigid material than silicon (Si), as a material for the edge ring 25 has been proposed, for the purpose of reducing abrasion of the edge ring 25 and extending the life of the edge ring 25. In the present embodiment, a highly plasma-resistant material that can further reduce abrasion of the edge ring 25 is proposed, in order to further extend the life of the edge ring 25.

Specifically, the edge ring 25 according to the present embodiment is formed of a material including silicon carbide and boron carbide. In the edge ring 25 according to the present embodiment, the content by percentage (may also be referred to as the “content”) of boron carbide contained in the material constituting the edge ring 25 is in the range between 30% and 50%.

### Film Structure

The plasma processing apparatus 1 performs a process of etching a layered film, formed of a silicon oxide film 102 and a silicon nitride film 103, which is formed on the substrate W, while the edge ring 25 formed of the above-described material is placed at the periphery of the substrate W in the chamber 10.

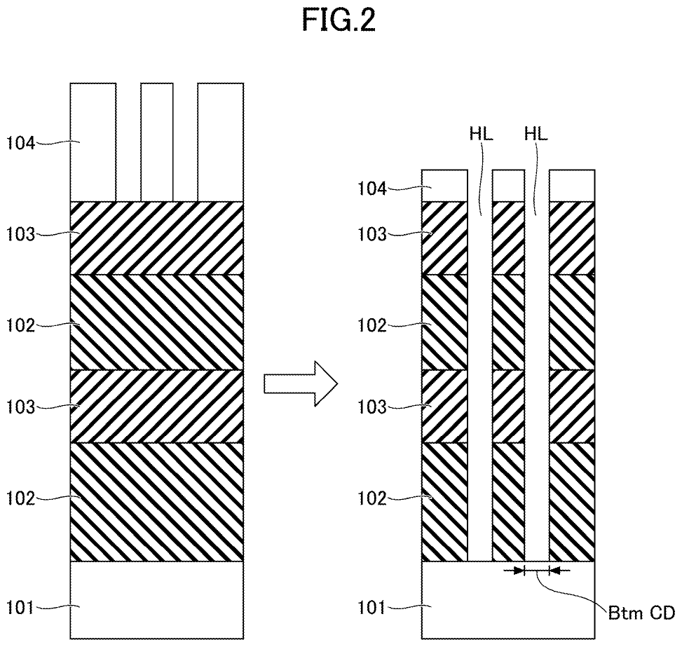

An example of a film structure on a substrate will be described with reference to FIG. 2. The diagram on the left side of FIG. 2 illustrates an example of the film structure formed on a substrate W according to the present embodiment. The substrate W has the film structure in which a silicon oxide film 102 (SiO₂) and a silicon nitride film 103 (SiN) are alternately layered one or more times on a silicon substrate 101. A mask film 104 is formed at the top of the film structure. The mask film 104 may be formed of, for example, polysilicon. The silicon oxide film 102 may be formed of SiOₓ containing SiO₂. The layering of the silicon oxide film 102 and the silicon nitride film 103 may be repeated in the order of the silicon oxide film 102 and the silicon nitride film 103, or may be repeated in the order of the silicon nitride film 103 and the silicon oxide film 102.

In the plasma processing apparatus 1, etching is applied to the substrate W having the above-described film structure, based on a given process condition using a plasma. The diagram on the right side of FIG. 2 illustrates a state in which the layered films of the silicon oxide film 102 and the silicon nitride film 103 are etched through the mask film 104, to form holes HL in the layered films. The width indicated by the arrow Btm CD (Bottom Critical Dimension) illustrated in the diagram on the right side of FIG. 2 indicates the diameter of the bottom of the hole. Examples of the above-describe etching include, but are not limited to, etching of a high aspect ratio contact (HARC) during DRAM manufacturing, and etching of a multi-level contacts of NAND-type memories.

By forming the edge ring 25 with a material including boron carbide and silicon carbide, the wear rate of the edge ring 25 can be reduced compared to the case in which an edge ring is composed of silicon and the case in which an edge ring is composed of silicon carbide. Hereinafter, experiments regarding abrasion of the edge ring 25 and results of the experiments will be described.

### Experimental results

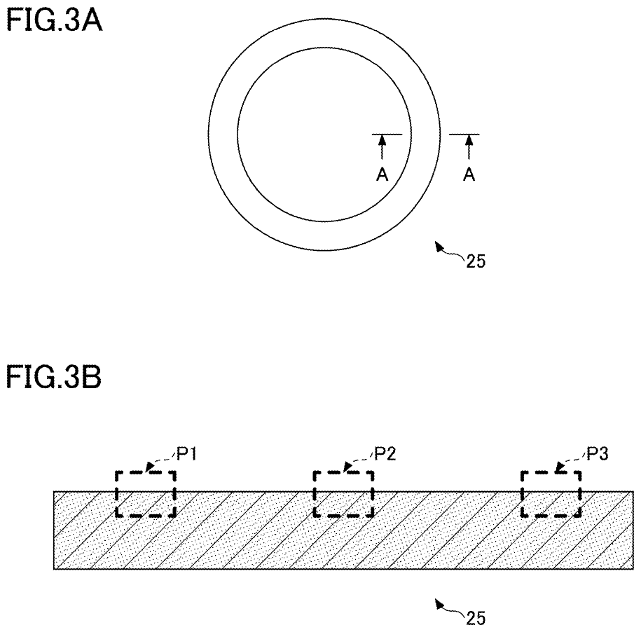

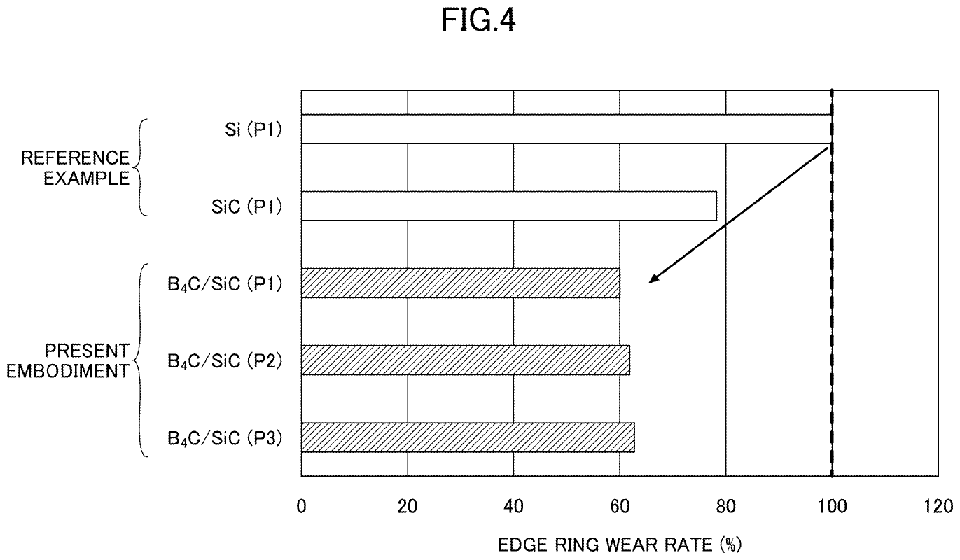

The experiments regarding abrasion of the edge ring 25 according to the present embodiment and the results of the experiment will be described, with reference to FIGS. 3A and 3B and FIG. 4. FIGS. 3A and 3B are diagrams illustrating the experiment regarding the abrasion of the edge ring 25 according to the present embodiment. FIG. 4 illustrates an example of results of the experiment regarding abrasion of the edge ring 25 according to the present embodiment.

FIG. 3A is a top view of the edge ring 25. The cross-section of the edge ring 25 taken along the line A-A is illustrated in FIG. 3B. In the present experiment, abrasion of the edge ring 25 at the positions (regions) P1, P2, and P3 in FIG. 3B was measured. The boron carbide content of the edge ring 25 used in the present experiment was 50%. The position P1 represents the location on the edge ring 25 closer to the inner circumference of the edge ring 25, the position P3 represents the location on the edge ring 25 closer to the outer circumference of the edge ring 25, and the position P2 represents the location on the edge ring 25 between the positions P1 and P3.

The abrasion of the edge ring 25 was calculated from the difference between the thickness of the edge ring 25 before etching and the thickness of the edge ring 25 after etching. The thickness of the edge ring 25 before etching represents the thickness when the edge ring 25 is new. The thickness of the edge ring 25 after etching is the thickness of the edge ring 25 after being exposed to a plasma and being abraded during etching.

In the present experiment, “before etching” means when the number of processed substrates W is zero, and “after etching” means when the number of processed substrates W reaches a predetermined number. However, the time when application time of power of the first radio frequency is 0 hours may be defined as “before etching”, and the time when the application time of the power of the first radio frequency reaches a predetermined value may be defined as “after etching”. The present experiment measured the wear rate of the edge ring 25, which was abraded by supplying a process gas containing fluorine gas into the chamber 10, forming the process gas into a plasma using power of the first radio frequency, and processing a predetermined number of substrates W using the plasma or processing the substrates W for a predetermined period of time. An example of the results of the present experiment is illustrated in FIG. 4.

The vertical axis of FIG. 4 indicates materials constituting the edge ring, and the horizontal axis indicates the wear rate (%) of the edge ring. The wear rate in FIG. 4 is defined as a ratio (%) of the abrasion amount of the edge ring to the abrasion amount of an edge ring according to a reference example that is formed of a material consisting of silicon (Si) (i.e., the abrasion amount of the edge ring when the abrasion amount of the edge ring according to the reference example that is formed of a material consisting of silicon (Si) is set to 100). The edge ring formed of a material consisting of silicon (Si) and the edge ring formed of a material consisting of silicon carbide (SiC) are reference examples. The edge ring 25 according to the present embodiment is formed of a material including boron carbide (B₄C) and silicon carbide (SiC). Bars illustrated at (P1) through (P3) on the vertical axis of FIG. 4 indicate the wear rates of the edge ring 25 at the positions P1 through P3 in FIG. 3B, respectively. For example, the bar illustrated at the position “B₄C/SiC (P1)” on the vertical axis indicates the wear rate at the position P1 of the edge ring 25 according to the present embodiment, and the bar illustrated at the position “Si (P1)” on the vertical axis indicates the wear rate at the position P1 of the edge ring according to the reference example (i.e., the edge ring formed of Si). As described earlier, the position P1 represents the location on the edge ring closer to the inner circumference of the edge ring, the position P3 represents the location on the edge ring closer to the outer circumference of the edge ring, and the position P2 represents the location on the edge ring between the positions P1 and P3.

According to the present experiment, the wear rate of the edge ring 25 according to the present embodiment was slightly higher at the outer circumferential side (i.e., position P3) than the inner circumferential side (i.e., position P1), but the difference between the wear rate at the outer circumferential side and the wear rate at the inner circumferential side was not so high. Comparing the present embodiment and the reference examples, the wear rate of the edge ring 25 according to the present embodiment was reduced by 40% compared to the edge ring consisting of silicon according to the first reference example, and slightly less than 20% compared to the edge ring consisting of silicon carbide according to the second reference example. As described above, according to the edge ring 25 of the present embodiment, as the edge ring is formed of a material including boron carbide and silicon carbide, the wear rate can be significantly reduced compared to the edge ring composed of silicon or silicon carbide according to the reference examples, and the plasma resistance can be improved.

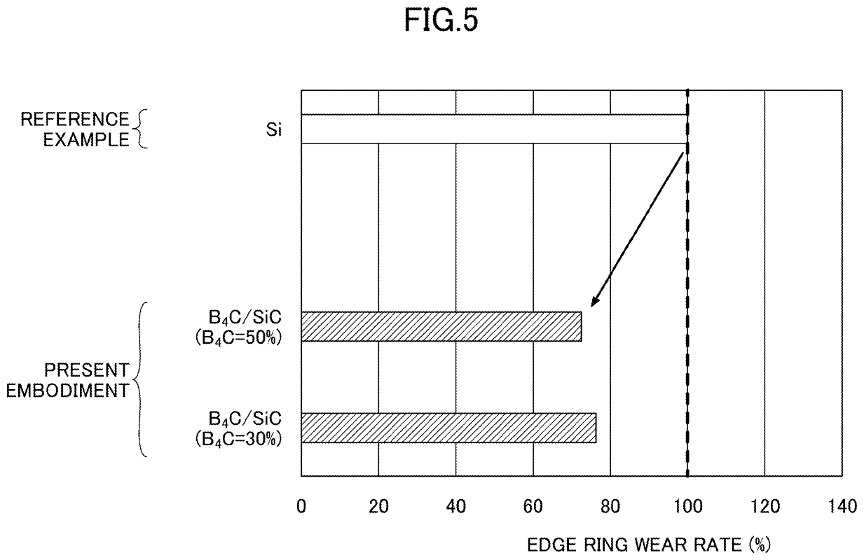

FIG. 5 is a diagram illustrating an example of experimental results regarding abrasion of a test piece of the edge ring 25 according to the present embodiment. The test piece used in the present experiment was formed of a material including boron carbide and silicon carbide, which was the same material as the edge ring 25 according to the present embodiment, and in the present experiment, a substrate W to which the test piece is attached was placed on the stage 14 of the plasma processing apparatus 1.

In the present experiment, a process gas containing fluorine gas was supplied into the chamber 10, and power at the first radio frequency was supplied. The magnitude of the power of the first radio frequency applied in the present experiment was 40% of the power of the first radio frequency that was applied during the experiment of FIG. 4. The process conditions other than the magnitude of the power of the first radio frequency were the same. Processing of the substrate W with a plasma of the process gas was performed for a predetermined period of time, and the abrasion of the test piece on the substrate W exposed to the plasma was measured. An example of the results of the present experiment is illustrated in FIG. 5.

The vertical axis of FIG. 5 indicates materials constituting the edge ring, and the horizontal axis of FIG. 5 indicates the wear rate (%) of the test piece of the edge ring 25 according to the present embodiment. The wear rate in FIG. 5 is defined as the abrasion amount of the test piece when the abrasion amount of an edge ring according to a reference example that is formed of a material consisting of silicon (Si) is 100. In the present experiment, the wear rate of a test piece formed of a material whose content of boron carbide is 50% (“B₄C=50%” in FIG. 5) and a test piece formed of a material whose content of boron carbide is 30% (“B₄C=30%” in FIG. 5) was measured.

Comparing the present embodiment illustrated in FIG. 5 with the reference example illustrated in FIG. 5, in a case in which the content of boron carbide is 50%, the wear rate of the test piece of the edge ring 25 according to the present embodiment was reduced by approximately 28% compared to the edge ring according to the reference example consisting of silicon, and in a case in which the content of boron carbide is 30%, the wear rate was reduced by approximately 25%.

In the experiment using the above-described test piece, as the magnitude of the power at the first radio frequency was different from the magnitude of the power at the first radio frequency applied in the experiment of FIG. 4, the wear rate in FIG. 4 differs from the wear rate in FIG. 5. However, if the magnitude of power applied is the same, the wear rate in the experiment of FIG. 5 becomes almost the same as the wear rate in the experiment of FIG. 4.

As described above, according to the edge ring 25 in the present embodiment, which is formed of a material including boron carbide and silicon carbide, in a case in which the content of boron carbide is in the range between 30% and 50%, the wear rate of the edge ring 25 can be reduced compared to the edge ring according to the reference example, which is formed of silicon carbide, and the plasma resistance can be improved. As a result, because the life of the edge ring 25 is extended, the replacement cycle of the edge ring 25 becomes longer and productivity of the plasma processing apparatus 1 improves.

### Etching Characteristics

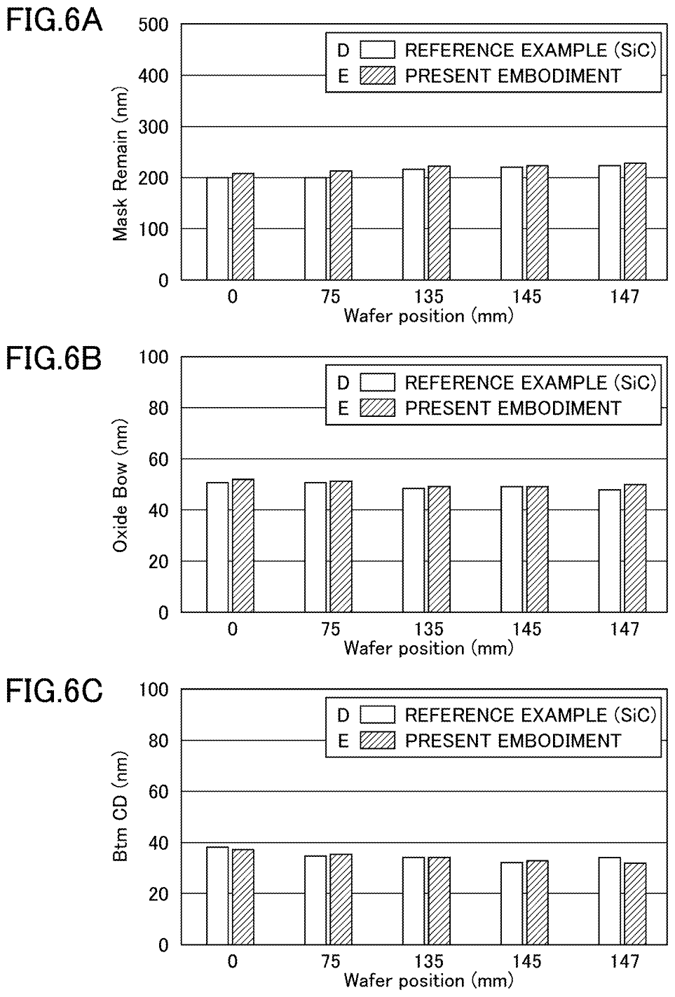

Next, examples of results of processing (e.g., etching process) of the substrate W in a case in which boron carbide and silicon carbide are used as the material of the edge ring 25 will be described with reference to FIG. 6. FIGS. 6A to 6C are diagrams illustrating examples of results of experiments of etching processing of a substrate performed in the plasma processing apparatus 1 in which the edge ring 25 according to the present embodiment is placed. In the etching performed in the present experiments, a substrate W on which a silicon nitride film 103 is formed is used.

The horizontal axes of FIGS. 6A to 6C indicate positions on a substrate (wafer) W having a diameter of 300 mm. 0 (mm) on the horizontal axis indicates the center of the substrate W. 75 (mm), 135 (mm), 145 (mm), and 147 (mm) indicate positions on the substrate N, which are 75 (mm), 135 (mm), 145 (mm), and 147 (mm) away from the center of the substrate W in the radial direction of the substrate. The vertical axis of FIG. 6A indicates the thickness of the mask film 104 remaining on the substrate W (hereinafter, the mask film 104 remaining on the substrate W may also be referred to as “mask remain”). The vertical axis of FIG. 6B indicates a state of bowing shape of a hole formed in the silicon oxide film 102 (e.g., a state in which the diameter of a portion of the hole HL is wider than other portions (see FIG. 2)). The vertical axis of FIG. 6C indicates the Btm CD (see FIG. 2) at the bottom of the hole.

The bar graphs D in FIGS. 6A to 6C respectively illustrate the mask remain (remaining amount of the mask) (FIG. 6A), the bowing shape (FIG. 6B), and the Btm CD (FIG. 6C), when an edge ring according to a reference example formed of a material consisting of silicon carbide was placed at the periphery of the substrate W. The bar graphs E in FIGS. 6A to 6C respectively illustrate the mask remain, the bowing shape, and the Btm CD when the edge ring 25 according to the present embodiment formed of a material including boron carbide and silicon carbide was placed at the periphery of the substrate W.

According to the results illustrated in FIGS. 6A to 6C, similar etching characteristics were exhibited in both cases, a case of using the edge ring according to the reference example (bar graph D), and a case of using the edge ring 25 according to the embodiment (bar graph E). That is, the size of the mask remain, the size of the bowing shape, and the size of the Btm CD in the case of using the edge ring according to the reference example were similar to those in the case of using the edge ring 25 according to the present embodiment.

From the foregoing, it has been found that use of the edge ring 25 according to the present embodiment formed of a material including boron carbide and silicon carbide exhibits the same etching characteristics as the case of using the edge ring formed of a material consisting of silicon carbide. That is, if the edge ring 25 according to the present embodiment formed of a material including boron carbide and silicon carbide is used, the plasma resistance can be improved as compared to the case of using the edge ring formed of a material consisting of silicon carbide or silicon carbide, without deteriorating the etching characteristics. Accordingly, the edge ring 25 according to the present embodiment can reduce the amount of abrasion of the edge ring 25, which is consumed by being exposed to a plasma for a certain period of time, as compared to the amount of abrasion of the edge ring according to the reference example that is exposed to a plasma for the same period of time as the edge ring 25 according to the present embodiment.

As described above, according to the edge ring 25 in the present embodiment, plasma resistance can be improved. In particular, the plasma resistance when etching a layered film of a silicon oxide film 102 and a silicon nitride film 103 can be improved.

The edge ring and the plasma processing apparatus according to the present embodiment disclosed herein should be considered only as an example in all respects, and should not be restrictive. The above embodiments may be modified and enhanced in various forms without departing from the scope of the appended claims. Matters described in the above embodiments may take other configurations to an extent not inconsistent, and may be combined to an extent not inconsistent.

The plasma processing apparatus according to the present disclosure is applicable to any type of apparatus, such as an atomic layer deposition (ALD) type, a capacitively coupled plasma (CCP) type, an inductively coupled plasma (ICP) type, a radial line slot antenna type (RLSA), an electron cyclotron resonance plasma (ECR) type, and a helicon wave plasma (HWP) type.

What is claimed is:

1. An edge ring formed of a material including boron carbide and silicon carbide, wherein a content by percentage of the boron carbide contained in the material is in a range between 30% and 50%.

2. The edge ring according to claim 1, wherein the edge ring is used in a plasma processing apparatus.

3. The edge ring according to claim 2, wherein,
when a substrate on which a layered film is formed is etched while the edge ring is placed to surround a periphery of the substrate in the plasma processing apparatus, the edge ring is exposed to a plasma, and
the layered film includes a silicon oxide film and a silicon nitride film.

4. A plasma processing apparatus comprising:
a chamber;
a stage on which a substrate is placed; and
an edge ring that is placed to surround a periphery of the substrate placed on the stage; wherein
the edge ring is formed of a material including boron carbide and silicon carbide, and
a content by percentage of the boron carbide contained in the material is in a range between 30% and 50%.
